(19) United States
(12) Patent Application Publication
(10) Pub. No.: US 2010/0237490 A1
(43) Pub. Date: Sep. 23, 2010

(54) PACKAGE STRUCTURE AND MANUFACTURING METHOD THEREOF

(76) Inventors: Chi-Chih CHU, Fengshan City (TW); Lin-Wang YU, Kaohsiung (TW)

Correspondence Address: Muncy, Geissler, Olds & Lowe, PLLC, 4000 Legato Road, Suite 310, FAIRFAX, VA, 22033, US

(21) Appl. No.: 12/561,627

(22) Filed: Sep. 17, 2009

(30) Foreign Application Priority Data
Mar. 20, 2009 (TW) 98109197

(51) Int. Cl. H01L 23/48; H01L 21/50

(52) U.S. Cl. 257/692; 438/118; 257/690; 438/120; 257/E21.499; 257/E23.116; 257/E23.01

(57) ABSTRACT

A package structure and a manufacturing method thereof are provided. The package structure includes a packaging substrate, a chip, an interposer substrate, a wire and an adhesive layer. The packaging substrate has an upper packaging surface. The chip is disposed on the upper packaging surface. The wire connects the packaging substrate and the interposer substrate. The adhesive layer is disposed between the packaging substrate and the interposer substrate, and covers the entire chip and part of the upper packaging surface. The adhesive layer includes a first adhesive part and a second adhesive part. The first adhesive part adheres the interposer substrate and the chip. The second adhesive part surrounds the first adhesive part, adheres the interposer substrate and the packaging substrate, and supports a periphery of the interposer substrate.

This application claims the benefit of Taiwan application Serial No. 98109197, filed Mar. 20, 2009, the subject matter of which is incorporated herein by reference.

### BACKGROUND OF THE INVENTION

1. Field of the Invention

The invention relates in general to a package structure and a manufacturing method thereof, and more particularly to a package structure adopting an interposer substrate and a manufacturing method thereof.

2. Description of the Related Art

Along with the development and advance in the semiconductor technology, various electronic products are provided one after another. A chip containing many micro-electronic elements may be disposed on a packaging substrate to form a package structure by a sealant, so that the chip is integrated on a printed circuit board and damages caused by external forces or moistures are avoided.

As more and higher requirements are expected of electronic products, an interposer substrate can further be used in addition to the packaging substrate to enhance the flexibility in the signal transduction pathways of the chip. However, the interposer substrate is easily damaged during the packaging process, and the quality of the package structure is hard to control. Thus, how to avoid the interposer substrate being damaged has become a focus in the development and research of the package structure.

### SUMMARY OF THE INVENTION

The invention is directed to a package structure and a manufacturing method thereof. The design of a soft adhesive layer enables the hardened and solidified adhesive layer to resist the force applied thereto by a gripper, hence effectively avoiding the interposer substrate being deformed.

According to a first aspect of the present invention, a package structure is provided. The package structure includes a packaging substrate, a chip, an interposer substrate, a wire and an adhesive layer. The packaging substrate has an upper packaging surface. The chip is disposed on an upper packaging surface. The wire connects the packaging substrate and the interposer substrate. The adhesive layer disposed between the packaging substrate and the interposer substrate covers the entire chip and part of the upper packaging surface. The adhesive layer includes a first adhesive part and a second adhesive part. The first adhesive part adheres the interposer substrate and the chip. The second adhesive part surrounds the first adhesive part, adheres the interposer substrate and the packaging substrate, and supports a periphery of the interposer substrate.

According to a second aspect of the present invention, a method of manufacturing package structure is provided. The manufacturing method o includes the following steps. A packaging substrate having an upper packaging surface is provided. A chip is disposed on the upper packaging surface. An interposer substrate is provided. An adhesive layer is disposed between the packaging substrate and the interposer substrate. The packaging substrate and the interposer substrate are adhered by the adhesive layer which covers the chip and part of the upper packaging surface, wherein the adhesive layer forms a first adhesive part and a second adhesive part, the first adhesive part adheres the interposer substrate and the chip, and the second adhesive part surrounds the first adhesive part, adheres the interposer substrate and the packaging substrate, and supports a periphery of the interposer substrate. The adhesive layer is solidified. The packaging substrate and the interposer substrate are connected by a first wire.

The invention will become apparent from the following detailed description of the preferred but non-limiting embodiments. The following description is made with reference to the accompanying drawings.

### BRIEF DESCRIPTION OF THE DRAWINGS

FIG. 1 shows a package structure according to a first embodiment of the invention;

FIGS. 2A˜2G show a flowchart of a method of manufacturing a package structure according to a first embodiment of the invention;

FIGS. 3A˜3B show a partial flowchart of a method of manufacturing a package structure according to a second embodiment of the invention;

FIG. 4 shows a package structure according to a third embodiment of the invention; and

FIG. 5 shows a package structure according to a fourth embodiment of the invention.

### DETAILED DESCRIPTION OF THE INVENTION

The invention is exemplified by a number of embodiments below. However, the following embodiments are for exemplification only, not for limiting the scope of protection of the invention. Moreover, only key elements relevant to the technology of the invention are illustrated, and secondary elements are omitted for highlighting the technical features of the invention

### First Embodiment

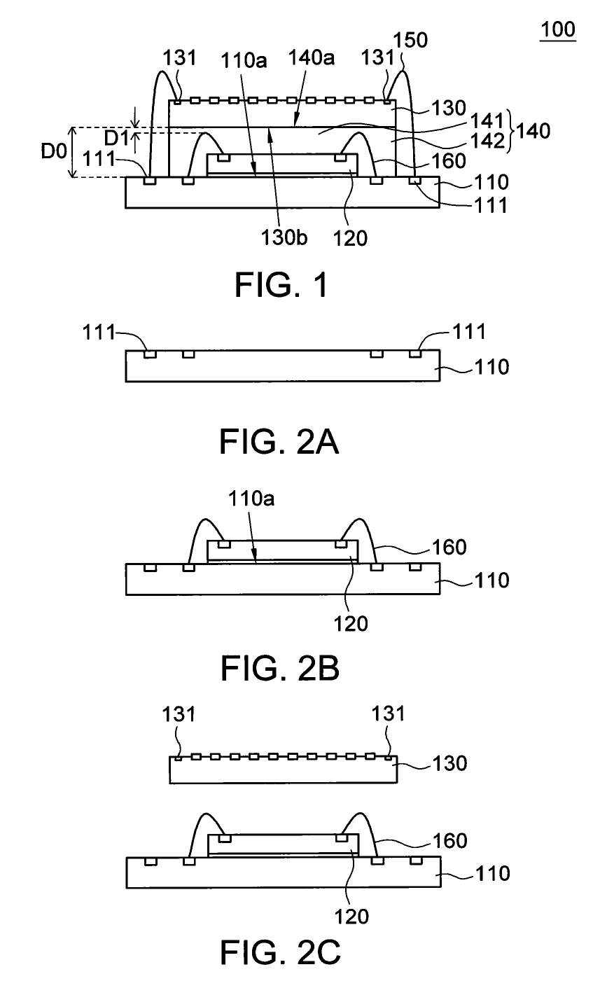

Referring to FIG. 1, a package structure 100 according to a first embodiment of the invention is shown. The package structure 100 includes a packaging substrate 110, a chip 120, an interposer substrate 130, a hardened adhesive layer 140, a first wire 150 and a second wire 160. The packaging substrate 110 can be a hard circuit board, a flexible circuit board or a lead frame. The packaging substrate 110 has an upper packaging surface 110a. The chip 120 is disposed on the upper packaging surface 110a of the packaging substrate 110. The interposer substrate 130 can be a hard circuit board or a lead frame. As indicated in FIG. 1, the interposer substrate 130 is projected from the edge of the chip 120, so the periphery of the interposer substrate 130 does not align to the chip 120. The first wire 150 connects the first solder pad 111 of the packaging substrate 110 and the second solder pad 131 of the interposer substrate 130. The second wire 160 connects the chip 120 and the packaging substrate 110.

The hardened adhesive layer 140 disposed between the packaging substrate 110 and the interposer substrate 130 entirely covers the chip 120 and the second wire 160, and part of the upper packaging surface 110a. The hardened adhesive layer 140 includes a hardened first adhesive part 141 and a hardened second adhesive part 142. The hardened first adhesive part 141 adheres the interposer substrate 130 and the chip 120. The hardened second adhesive part 142 surrounds the hardened first adhesive part 141, adheres the interposer substrate 130 and the packaging substrate 110, and supports a periphery of the interposer substrate 130.

Besides, the area of an upper surface 140a of the hardened adhesive layer 140 is substantially equal to that of a lower surface 130b of the interposer substrate 130. That is, the interposer substrate 130 is completely supported by the hardened adhesive layer 140.

In the present embodiment of the invention, the thickness D0 of the hardened adhesive layer 140 is at least 120 μm. The distance D1 between a top end of the second wire 160 and the lower surface 130b of the interposer substrate 130 is at least 10 μm. Thus, it is assured that the hardened adhesive layer 140 covers the entire second wire 160, and the interposer substrate 130 does not press the second wire 160.

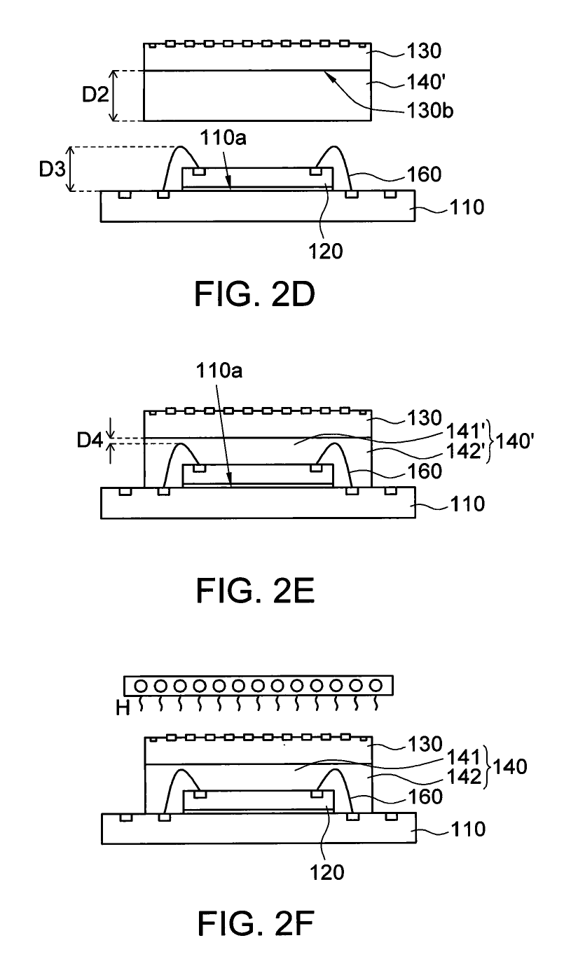

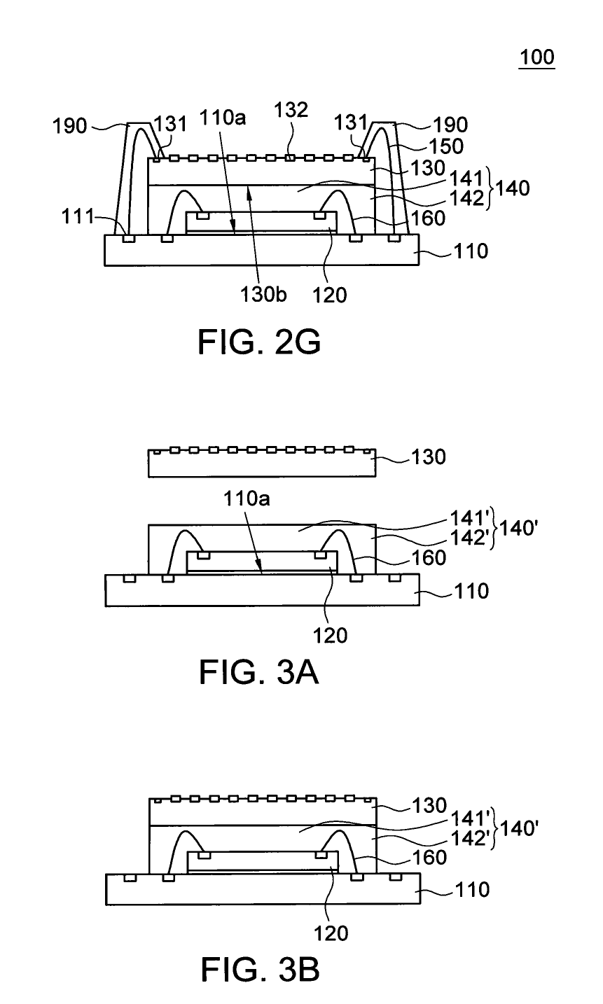

The hardened adhesive layer 140 is made from a thermosetting adhesive material, such as a B-stage resin. Before hardening, the hardened adhesive layer 140 is a soft adhesive layer 140′ (illustrated in FIG. 2D) being adhesive and deformable. After hardening, the hardened adhesive layer 140 is no longer deformable. Thus, the interposer substrate 130 is supported by the chip 120 as well as by the hardened second adhesive part 142 of the hardened adhesive layer 140. Compared with the conventional package structure (not illustrated), the interposer substrate 130 of the package structure 100 of the present embodiment of the invention, being supported to a larger extent, resists the force applied thereto and will not be deformed when forming the first wire 150 on the interposer substrate 130.

Referring to FIGS. 2A˜2G, a flowchart of a method of manufacturing a package structure 100 according to a first embodiment of the invention is shown. Firstly, as indicated in FIG. 2A, the packaging substrate 110 is provided. According to the needs of the product, the packaging substrate 110 can select a hard circuit board, a package flexible circuit board or a lead frame. Meanwhile, the packaging substrate 110 is already equipped with a necessary circuit and a first solder pad 111.

Next, as indicated in FIG. 2B, the chip 120 is disposed on the upper packaging surface 110a of the packaging substrate 110. In the present embodiment of the invention, the chip 120 is wire bonded on the upper packaging surface 110a of the packaging substrate 110. As indicated in FIG. 2B, in the present step, the chip 120 and the packaging substrate 110 are electrically connected with each other by a second wire 160.

Then, as indicated in FIG. 2C, the interposer substrate 130 is provided. According to the needs of the product, the interposer substrate 130 can select a hard circuit board or a lead frame. Meanwhile, the interposer substrate 130 is already equipped with a necessary circuit and a second solder pad 131.

Next, as indicated in FIG. 2D, the soft adhesive layer 140′ is provided. In the present embodiment of the invention, the soft adhesive layer 140′ is disposed on the lower surface 130b of the interposer substrate 130 through stencil printing. As indicated in FIG. 2D, the soft adhesive layer 140′ is disposed on the interposer substrate 130, wherein the soft adhesive layer 140′ not only corresponds to the chip 120 but also corresponds to part of the upper packaging surface 110a. Meanwhile, the soft adhesive layer 140′ is not yet solidified and is still deformable.

The soft adhesive layer 140′ is a thick film whose thickness D2 is greater than the distance D3 between a top end of the second wire 160 and the upper packaging surface 110a. In the present embodiment of the invention, the thickness D2 of the soft adhesive layer 140′ is at least 120 μm.

Afterwards, as indicated in FIG. 2E, the packaging substrate 110 and the interposer substrate 130 are adhered by the soft adhesive layer 140′. In the present embodiment of the invention, the soft adhesive layer 140′ is disposed between the packaging substrate 110 and the interposer substrate 130 according to the film on wire (FOW) technology. Let FIG. 2E be taken for example. The soft adhesive layer 140′ is deformable. As the distance between the packaging substrate 110 and the interposer substrate 130 becomes smaller, the chip 120 and the second wire 160 can be completely embedded into the soft adhesive layer 140′, and the soft adhesive layer 140′entirely covers the chip 120, the second wire 160, and the upper packaging surface 110a of the packaging substrate 110 surrounding the chip 120. Meanwhile, the soft adhesive layer 140′ forms a soft first adhesive part 140′ and a soft second adhesive part 142′. The soft first adhesive part 141′ adheres the interposer substrate 130 and the chip 120. The soft second adhesive part 142′ surrounds the soft first adhesive part 141′, adheres the interposer substrate 130 and the packaging substrate 110, and supports the periphery of the interposer substrate 130 the periphery.

As the thickness D2 (illustrated in FIG. 2D) of the soft adhesive layer 140′ is greater than the distance D3 (illustrated in FIG. 2D) between the top end of the second wire 160 and the upper packaging surface 110a, there is a distance D4 between the top end of the second wire 160 and the lower surface 130b of the interposer substrate 130 when the soft adhesive layer 140′ covers the entire second wire 160. In the present embodiment of the invention, the distance D4 is at least 10 μm.

Next, as indicated in FIG. 2F, the soft adhesive layer 140′ is solidified. In the present embodiment of the invention, a heat energy H is provided for solidifying the soft adhesive layer 140′ to form the hardened adhesive layer 140. Meanwhile, the hardened adhesive layer 140 includes the hardened first adhesive part 141 and the hardened second adhesive part 142. The hardened first adhesive part 141 is formed from the soft first adhesive part 141′, and the hardened second adhesive part 142 is formed from the soft second adhesive part 142′. The hardened first adhesive part 141 adheres the interposer substrate 130 and the chip 120. The hardened second adhesive part 142 surrounds the hardened first adhesive part 141, adheres the interposer substrate 130 and the packaging substrate 110, and supports a periphery of the interposer substrate 130. The hardened adhesive layer 140 being solidified is no longer deformable and provides the interposer substrate 130 with sufficient supporting strength.

Then, as indicated in FIG. 2G, the packaging substrate 110 and the interposer substrate 130 are connected by the first wire 150. During the process of soldering the first wire 150, the hardened adhesive layer 140 being solidified resists the force applied to the second solder pad 131 by the gripper, hence effectively avoiding the interposer substrate 130 being deformed.

Further, as indicated in FIG. 2G, a molding compound 190 covers the first wire 150, part of the interposer substrate 130 and part of the hardened adhesive layer 140, and expose a plurality of third solder pads 132.

### Second Embodiment

Referring to FIG. 3A-3B, a partial flowchart of a method of manufacturing a package structure 100 according to a second embodiment of the invention is shown. In the method of manufacturing package structure 100 of the present embodiment of the invention, FIGS. 3A˜3B replace FIGS. 2D˜2E of the first embodiment, and other similarities are not repeated.

In the present embodiment of the invention, the method proceeds to FIG. 3A after FIGS. 2A˜2C are completed. The soft adhesive layer 140′ of the present embodiment of the invention is formed on the upper packaging surface 110a of the packaging substrate 110 of the chip 120 through stencil printing.

Then, as indicated in FIG. 3B, the packaging substrate 110 and the interposer substrate 130 are adhered by a soft adhesive layer 140′. As the soft adhesive layer 140′ already covers the chip 120 and the second wire 160, the present step only needs to place the interposer substrate 130 on the soft adhesive layer 140′.

Lastly, the package structure 100 is completed after FIGS. 2F˜2G are executed.

### Third Embodiment

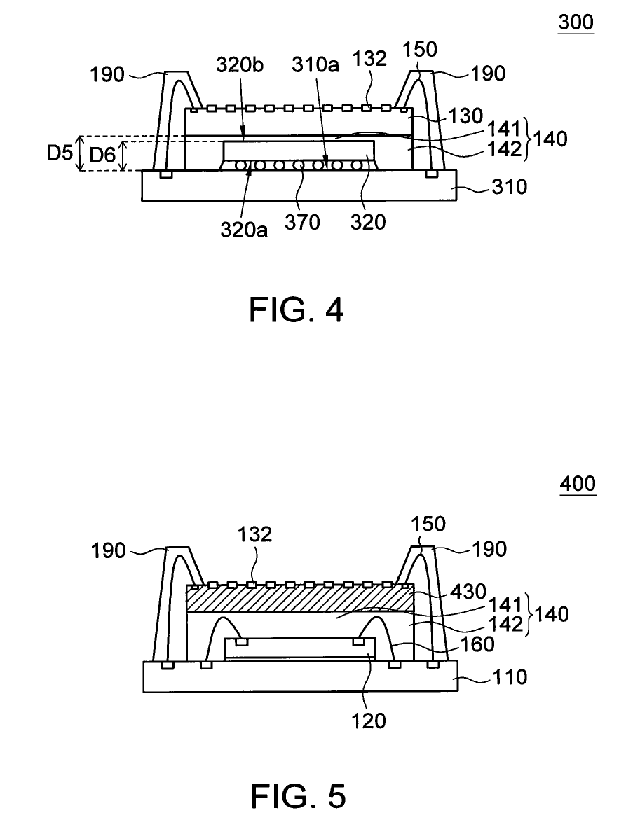

Referring to FIG. 4, a package structure 300 according to a third embodiment of the invention is shown. The package structure 300 of the present embodiment of the invention differs with the package structure 100 of the first embodiment in that the chip 320 of the package structure 300 of the present embodiment of the invention is disposed on an upper packaging surface 310a of the packaging substrate 310 through flip chip bonding, and other similarities are not repeated here.

As indicated in FIG. 4, the package structure 300 of the present embodiment of the invention includes a plurality of conductive bumps 370 disposed on an active surface 320a of the chip 320. The chip 320 can be electrically connected to the packaging substrate 310 via the conductive bumps 370 for electrical signals to be communicated.

The hardened adhesive layer 140 of the present embodiment of the invention is a thick film whose thickness D5 is greater than the distance D6 between a back surface 320b of the chip 320 and the upper packaging surface 310a. Wherein the back surface 320b is opposite to the active surface 320a.

The method of manufacturing a package structure 300 of the present embodiment of the invention adopts a method similar to that of manufacturing a package structure 100 of the first embodiment or the second embodiment, and the similarities are not repeated here.

### Fourth Embodiment

Referring to FIG. 5, a package structure 400 according to a fourth embodiment of the invention is shown. The package structure 400 of the present embodiment of the invention differs with the package structure 100 of the first embodiment in that the interposer substrate 430 of the package structure 400 of the present embodiment of the invention comprises a fingerprint sensor, and other similarities are not repeated here.

As indicated in FIG. 5, in order to meet the needs in the design of some products, the interposer substrate 430 comprises a fingerprint sensor. When the interposer substrate 430 comprises a fingerprint sensor, the supporting strength of the interposer substrate 430 is further improved through the design of the hardened adhesive layer 140.

The method of manufacturing a package structure 400 of the present embodiment of the invention adopts a method similar to that of manufacturing a package structure 100 of the first embodiment or the second embodiment, and the similarities are not repeated here.

According to the package structure and the manufacturing method thereof disclosed in above embodiments of the invention, the design of a soft adhesive layer enables the hardened adhesive layer being solidified to resist the force applied thereto by the gripper, hence effectively avoiding the interposer substrate being deformed.

While the invention has been described through example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure, comprising:
a packaging substrate having an upper packaging surface;
a chip disposed on the upper packaging surface;
an interposer substrate;
a first wire electrically connecting the packaging substrate and the interposer substrate; and
an adhesive layer disposed between the packaging substrate and the interposer substrate, and covering the entire chip and part of the upper packaging surface, wherein the adhesive layer comprises:
a first adhesive part adhering the interposer substrate and the chip; and
a second adhesive part surrounding the first adhesive part, adhering the interposer substrate and the packaging substrate, and supporting a periphery of the interposer substrate.

2. The package structure according to claim 1, further comprising:
a second wire electrically connecting the chip and the packaging substrate, wherein the adhesive layer further entirely covers the second wire.

3. The package structure according to claim 1, further comprising:
a plurality of conductive bumps disposed between the chip and the packaging substrate.

4. The package structure according to claim 1, wherein the interposer substrate comprises a fingerprint sensor.

5. The package structure according to claim 1, wherein the adhesive layer is made from a B-stage resin.

6. The package structure according to claim 1, wherein the area of an upper surface of the adhesive layer is substantially equal to that of a lower surface of the interposer substrate.

7. The package structure according to claim 1, wherein the thickness of the adhesive layer is at least 120 μm.

8. The package structure according to claim 1, wherein there is a gap located between a top end of the second wire and a lower surface of the interposer substrate.

9. The package structure according to claim 8, wherein the distance between the top end of the second wire and the lower surface of the interposer substrate is at least 10 μm.

10. A method of manufacturing packaging structure, comprising:
(a) providing a packaging substrate having an upper packaging surface;
(b) disposing a chip on the upper packaging surface;
(c) providing an interposer substrate;
(d) disposing an adhesive layer between the packaging substrate and the interposer substrate;
(e) connecting the packaging substrate and the interposer substrate by the adhesive layer which covers the chip and part of the upper packaging surface, wherein the adhesive layer has a first adhesive part and a second adhesive part, the first adhesive part adheres the interposer substrate and the chip, and the second adhesive part surrounds the first adhesive part, adheres the interposer substrate and the packaging substrate and supports a periphery of the interposer substrate;
(f) hardening the adhesive layer; and
(g) electrically connecting the packaging substrate and the interposer substrate by a first wire.

11. The manufacturing method according to claim 10, wherein in the step (d), the adhesive layer is disposed on a lower surface of the interposer substrate.

12. The manufacturing method according to claim 11, wherein in the step (d), the adhesive layer is disposed on the lower surface of the interposer substrate through stencil printing.

13. The manufacturing method according to claim 10, wherein in the step (d), the adhesive layer is disposed on the upper packaging surface of the packaging substrate having the chip.

14. The manufacturing method according to claim 13, wherein in the step (d), the adhesive layer is disposed on the upper packaging surface of the packaging substrate having the chip through stencil printing.

15. The manufacturing method according to claim 10, wherein in the step (b), the chip and the packaging substrate are electrically connected by a second wire, and in the step (e), the second wire is entirely covered by the adhesive layer.

16. The manufacturing method according to claim 15, wherein in the step (d), a thickness of the adhesive layer is greater than a distance between a top end of the second wire and the upper packaging surface.

17. The manufacturing method according to claim 10, wherein in the step (b), the chip is electrically connected to the packaging substrate via a plurality of conductive bumps.

18. The manufacturing method according to claim 17, wherein in the step (d), a thickness of the adhesive layer is greater than a distance between a back surface of the chip and the upper packaging surface.

19. The manufacturing method according to claim 10, wherein in the step (c), the interposer substrate comprises a fingerprint sensor.
